(19) United States
(12) Patent Application Publication
(10) Pub. No.: US 2012/0299171 A1
(43) Pub. Date: Nov. 29, 2012

(54) LEADFRAME-BASED BALL GRID ARRAY PACKAGING

(75) Inventors: Curtis Grosskopf, Hyde Park, NY (US); Alfredo Fappiano, Torrington, CT (US)

(73) Assignee: INTERNATIONAL BUSINESS MACHINES CORPORATION, Armonk, NY (US)

(21) Appl. No.: 13/117,356

(22) Filed: May 27, 2011

(51) Int. Cl. H01L 23/495; H01L 21/60

(52) U.S. Cl. 257/673; 438/123; 257/E23.033; 257/E21.506

(57) ABSTRACT

A metal sheet is patterned into a leadframe that includes metal wiring structures one side and metal pads arranged for ball grid array (BGA) style connection on the other side. A semiconductor chip is bonded to the leadframe, for example, by solder balls that are reflowed onto the side of the leadframe that includes the metal wiring structures. The metal wiring structures provide interconnection among solder balls as needed. Peripheral portions of the leadframe are removed. The bonded structure is embedded in a dielectric molding compound that embeds, and provides mechanical support for, lead structures and the solder balls. The composite structure including the bonded structure and the dielectric molding compound can be bonded to a substrate employing an array of BGA balls that is bonded to the metal pads of the lead structures embedded in the dielectric molding compound.

### BACKGROUND

The present disclosure relates to a structure and a method for bonding substrates, and particularly to a structure and a method of bonding leadframe-based package to a substrate employing ball grid array packaging.

Use of power liner devices in a ball grid array (BGA) style chip scale package (CSP) to attach a semiconductor chip to a substrate, such as a printed circuit board, can cause electrical opens and/or shorts during a card assembly process as the pitch of the balls decreases below 500 microns. Mechanical damage to a package predominantly including silicon material is also observed during card assembly.

A flip chip Quad Flat No leads (“fcQFN”) package was developed to reduce the number of interconnects by more than 50%, while providing the same level of performance and current carrying capabilities of a BGA style CSP. An fcQFN is encapsulated to provide more mechanical protection. Some of the power linear devices in an fcQFN have been demonstrated to carry more than 50 amperes. However, the fcQFN has been shown to have poor second level reliability, i.e., poor reliability at solder joints with a printed circuit board. The solder joint reliability problem has been particularly acute when lead-free solder was employed with attached heat sinks. Thus, there are some concerns on the reliability of fcQFN packages.

Use of larger diameter solder balls, while enhancing the reliability of a CSP package, requires a larger silicon die, and therefore, increases the component cost, takes up more space on a printed circuit board, and have a greater potential for physical damage. Further, such a change also requires redesign of a device at a metal layer. While use of a Quad Flat Package (“QFP”) can also be contemplated to provide enhanced reliability through increased standoff between a package and a printed circuit board, such a change increases the footprint on the printed circuit board.

### BRIEF SUMMARY

A metal sheet is patterned into a leadframe that includes metal wiring structures on one side and metal pads arranged for ball grid array (BGA) style connection on the other side. A semiconductor chip is bonded to the leadframe, for example, by solder balls that are reflowed onto the side of the leadframe that includes the metal wiring structures. The metal wiring structures provide interconnection among solder balls as needed. Peripheral portions of the leadframe are removed. The bonded structure includes the semiconductor chip, the solder balls, and lead structures that include disjoined wiring structures and metal pads thereupon. The bonded structure is embedded in a dielectric molding compound that embeds, and provides mechanical support for, the lead structures and the solder balls. The composite structure including the bonded structure and the dielectric molding compound can be bonded to a substrate employing an array of BGA balls that is bonded to the metal pads of the lead structures embedded in the dielectric molding compound.

According to an aspect of the present disclosure, a packaging structure including a composite structure is provided. The composite structure includes: a semiconductor chip including at least one semiconductor device therein; solder balls bonded to the semiconductor chip; a set of lead structures bonded to the solder balls, wherein each lead structure among the set of lead structures includes an integral construction of a planar metal wiring structure located on one side and at least one metal pad protruding from a surface of the planar metal wiring structure on the other side; and a dielectric molding compound structure of integral construction, the dielectric molding compound structure embedding the semiconductor chip, the solder balls, and the set of lead structures.

According to another aspect of the present disclosure, a method of bonding a semiconductor chip to a substrate is provided. The method includes: forming a composite structure including a semiconductor chip, solder balls bonded to the semiconductor chip, a set of lead structures bonded to the solder balls, and a dielectric molding compound structure of integral construction, the dielectric molding compound structure embedding the semiconductor chip, the solder balls, and the set of lead structures, wherein each lead structure among the set of lead structures includes an integral construction of a planar metal wiring structure located on one side and at least one metal pad protruding from a surface of the planar metal wiring structure on the other side; bonding an array of ball grid array (BGA) balls to surfaces of the metal pads; and bonding a substrate to the array of BGA balls.

### BRIEF DESCRIPTION OF THE SEVERAL VIEWS OF THE DRAWINGS

FIG. 1A is a top down view of an exemplary structure including a metal sheet and a first etch mask formed thereupon according to an embodiment of the present disclosure.

FIG. 1B is a vertical cross-sectional view of the exemplary structure of FIG. 1A along the vertical plane B-B′ according to an embodiment of the present disclosure.

FIG. 2A is a top down view of the exemplary structure after etching exposed portions of an upper layer of the metal sheet according to an embodiment of the present disclosure.

FIG. 2B is a vertical cross-sectional view of the exemplary structure of FIG. 2A along the vertical plane B-B′ according to an embodiment of the present disclosure.

FIG. 3A is a bottom up view of the exemplary structure after etching a lower layer of the metal sheet employing a second etch mask to form a leadframe according to an embodiment of the present disclosure.

FIG. 3B is a vertical cross-sectional view of the exemplary structure of FIG. 3A along the vertical plane B-B′ according to an embodiment of the present disclosure.

FIG. 4A is a top down view of the exemplary structure while bringing a semiconductor chip with solder balls into contact with the leadframe according to an embodiment of the present disclosure.

FIG. 4B is a vertical cross-sectional view of the exemplary structure of FIG. 4A along the vertical plane B-B′ according to an embodiment of the present disclosure.

FIG. 5A is a top down view of the exemplary structure after bonding the semiconductor chip with the leadframe and during truncation of the periphery of the leadframe according to an embodiment of the present disclosure.

FIG. 5B is a vertical cross-sectional view of the exemplary structure of FIG. 5A along the vertical plane B-B′ according to an embodiment of the present disclosure.

FIG. 6A is a top down view of the exemplary structure after applying a molding compound on the bonded structure to form a composite structure according to an embodiment of the present disclosure.

FIG. 6B is a vertical cross-sectional view of the exemplary structure of FIG. 6A along the vertical plane B-B′ according to an embodiment of the present disclosure.

FIG. 6C is a horizontal cross-sectional view of the exemplary structure of FIGS. 6A and 6B along the plane C-C′ in FIG. 6B according to an embodiment of the present disclosure.

FIG. 6D is a horizontal cross-sectional view of the exemplary structure of FIGS. 6A and 6B along the plane D-D′ in FIG. 6B according to an embodiment of the present disclosure.

FIG. 6E is a horizontal cross-sectional view of the exemplary structure of FIGS. 6A and 6B along the plane E-E′ in FIG. 6B according to an embodiment of the present disclosure.

FIG. 7A is a bottom up view of the exemplary structure after attaching ball grid array (BGA) balls to the metal pads on lead structures in the composite structure according to an embodiment of the present disclosure.

FIG. 7B is a vertical cross-sectional view of the exemplary structure of FIG. 7A along the vertical plane B-B′ according to an embodiment of the present disclosure.

FIG. 8 is a vertical cross-sectional view of the exemplary structure after bonding the composite structure to a substrate through the array of BGA balls.

### DETAILED DESCRIPTION

As stated above, the present disclosure relates to a structure and a method of bonding leadframe-based package to a substrate employing ball grid array packaging, which is now described in detail with accompanying figures. It is noted that like and corresponding elements are referred to by like reference numerals. The drawings are not in scale.

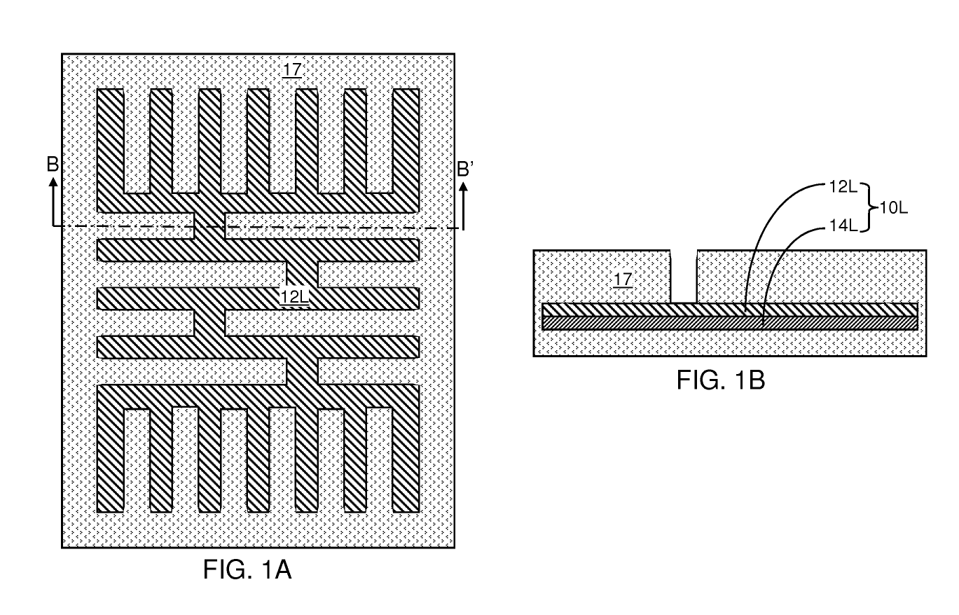

Referring to FIGS. 1A and 1B, a first etch mask 17 is formed on a metal sheet 10L such that the back side and side surfaces of the metal sheet 10L are completely covered by the first etch mask 17, while a contiguous portion of the top surface of the metal sheet 10L is exposed. The metal sheet 10L includes a conductive metallic material such as copper, silver, aluminum, gold, or a combination thereof. The metal sheet 10L can have the same thickness throughout. The metal sheet 10L can have the same composition throughout the entirety thereof. The thickness of the metal sheet 10L can be from 50 microns to 3 mm, and typically from 100 microns to 1 mm, although lesser and greater thicknesses can also be employed.

While the metal sheet 10L is depicted as a composite structure of an upper layer and a lower layer, the upper layer and the lower layer are of integral construction, i.e., in a single piece, without any physically manifested interface therebetween. The upper layer is herein referred to as a front-side metal layer 12L, and the lower layer is herein referred to as a back-side metal layer 14L. Thus, the division of the metal sheet 10L into the front-side metal layer 12L and the back-side metal layer 14L in the drawings is only for the purpose of illustrating two different patterns to be transferred into the metal sheet 10L.

The first etch mask 17 can be patterned in any manner known in the art. For example, the first etch mask 17 can includes a photosensitive material that can be patterned by photolithographic exposure and development. Alternately, the first etch mask 17 can be mechanically patterned by removing portions of a planar material layer employed for the first etch mask by mechanical means or by laser ablation, or by stamping an upper portion of the first etch mask employing a patterned surface.

The material of the first etch mask 17 can be a photosensitive material, a polymer, or any other material that can function as an etch mask during a subsequent etch process. The pattern in the first etch mask 17 is formed such that the pattern of the blocked areas, i.e., the areas covered by the material of the first etch mask 17, correspond to areas of conductive paths in a planar wiring structure to be patterned from the upper portion of the metal sheet 10L, i.e., from the front-side metal sheet layer 12L. The conductive paths are designed for a semiconductor chip of a preselected type to be packaged employing lead structures to be subsequently derived from the metal sheet 10L upon further patterning. Specifically, the conductive paths are designed to provide lateral electrical connection to solder balls to be subsequently bonded to the semiconductor chip.

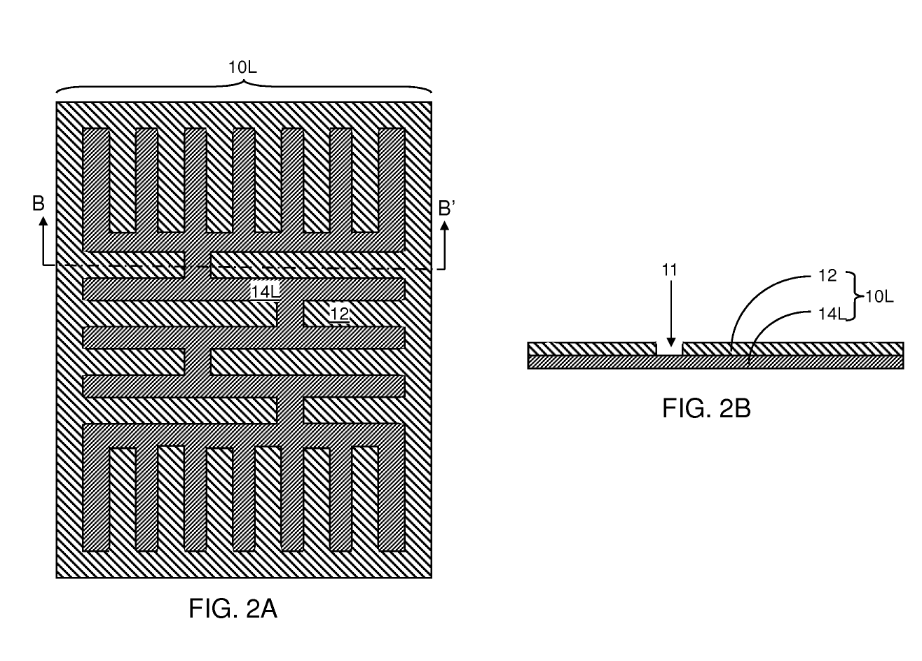

Referring to FIGS. 2A and 2B, exposed portions of the front-side metal layer 12L are etched, for example, by a wet etch that removes the metallic material of the front-side metal layer 12L. The first etch mask 17 protects the back-side metal layer 14L and the covered regions of the front-side metal layer 12L. The front-side metal layer 12L as etched includes a pattern for planar metal wiring structures, i.e., metal wiring structures having planar top surfaces.

The bottom the interface between the front-side metal layer 12L and the back-side metal layer 14L is defined to coincide with the etch depth into the metal layer 10. The back-side metal layer 14L is defined as the portion of the metal layer 10 between the recessed surfaces caused by the etch and the original back side surface of the metal layer 10. Correspondingly, the front-side metal layer 12L is defined as the portion of the metal layer between the original top surface and the recessed surfaces.

Thus, the remaining portion of the front-side metal layer 12L is a planar patterned metal structure 12 having the same thickness throughout. The planar patterned metal structure 12 includes a plurality of planar metal wiring structures, each of which extends in a lateral direction. In one embodiment, the planar metal wiring structures in the planar patterned metal structure 12 can have a width on the order of a BGA ball, i.e., a width from 300 microns to 700 microns, although lesser and greater widths can also be employed. The thickness of the front-side metal layer 12L is the same as the recess depth of the trenches 11 formed on the front side of the metal sheet 10L. The first etch mask 17 is removed selective to the metal sheet 10L. The planar patterned metal structure 12 includes conductive paths configured for laterally electrically connecting solder balls bonded to a semiconductor chip of a predetermined type.

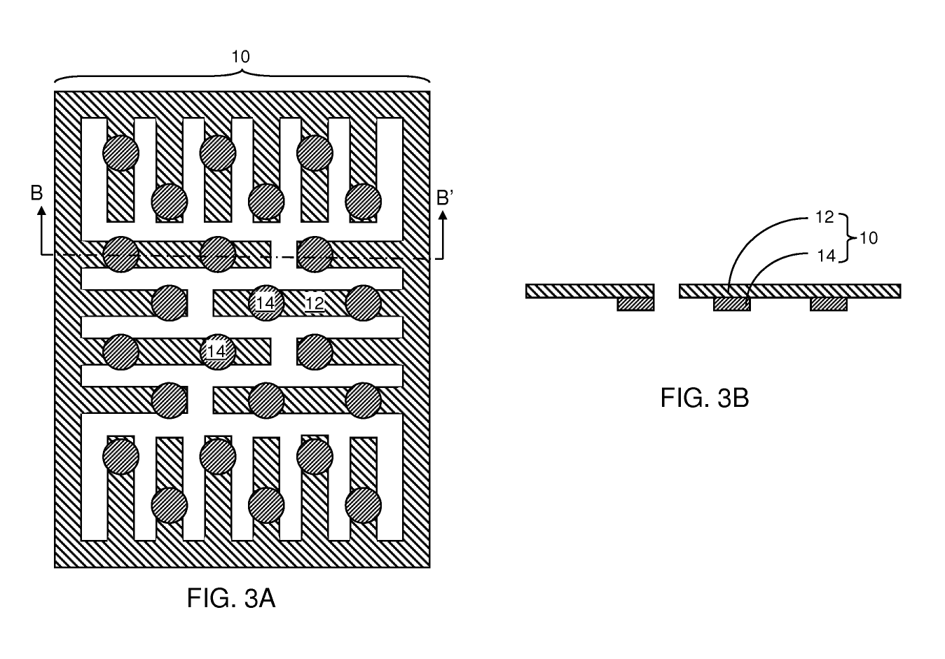

Referring to FIGS. 3A and 3B, a second etch mask (not shown) is employed in a manner similar to the processing steps of FIGS. 1A, 1B, 2A, and 2B to pattern the back-side metal layer 14L, while covering and protecting the exposed surfaces of the planar patterned metal structure 12. Specifically, all espoused surface of the planar patterned metal structure 12 can be protected by the second etch mask, while the exposed backside surfaces of the back-side metal layer 14L are protected only in areas corresponding to locations at which ball grid array (BGA) balls are to be bonded to a structure, which is a leadframe, to be derived from the metal sheet 10L.

Exposed portions of the back-side metal layer 14L are etched, for example, by a second wet etch that removes the metallic material of the back-side metal layer 14L. The second etch mask protects the planar patterned metal structure 12 and the covered regions of the back-side metal layer 14L. The back-side metal layer 14L as etched includes a pattern for metal pads 14 having a diameter on the order of the diameter of BGA balls to be subsequently bonded thereto.

A center portion of each metal pad 14 overlaps with one of the planar metal wiring structures within the planar patterned metal structure 12. The metal pads 14 can have the shapes of cylinders having a circular cross-sectional area and having the thickness of the back-side metal layer 14L. The metal pads 14 are arranged in a pattern compatible with an array of BGA balls, which can be, for example, a rectangular array, a square array, a hexagonal array, or any other type of regular array. In one embodiment, a “peripheral array”, in which there are several rows of balls in an array pattern around the periphery of a square or rectangular package, can be employed as the pattern for the metal pads 14. The array of the metal pads 14 may, or may not, be fully populated depending on embodiments. The planar patterned metal structure 12 and the metal pads 14 are designed such that each metal pad 14 overlaps at least a portion of the planar patterned metal structure 12. In one embodiment, the center of each metal pad 14 is located within the area of the planar patterned metal structure 12. The planar patterned metal structure 12 can overlap at least 50%, and typically more than 80%, and more typically more than 90% of the area of each metal pad 14.

Each metal pad has the same thickness, which is the thickness of the back-side metal layer. The thickness of the planar patterned metal structure 12 and the thickness of a metal pad 14 add up to the thickness of the metal sheet 10L as originally provided. The thickness of the planar patterned metal structure 12 can be from 25 microns to 1.5 mm, and typically from 50 microns to 500 microns, although lesser and greater thicknesses can also be employed. The thickness of the metal pads 14 can be from 25 microns to 1.5 mm, and typically from 50 microns to 500 microns, although lesser and greater thicknesses can also be employed.

The combination of the planar patterned metal structure 12 and the metal pads 14 collectively constitute a leadframe 10. The leadframe 10 is a structure of unitary construction, i.e., for any two arbitrarily chosen points within the leadframe 10, there exists at least one continuous path confined within the volume of the leadframe 10 that connects the two points. Typically, the entirety of the leadframe is structurally supported and contiguously connected by a peripheral frame that holds the metal pads 14 through the various portions of the planar patterned metal structure 12 that protrude inward from the peripheral frame.

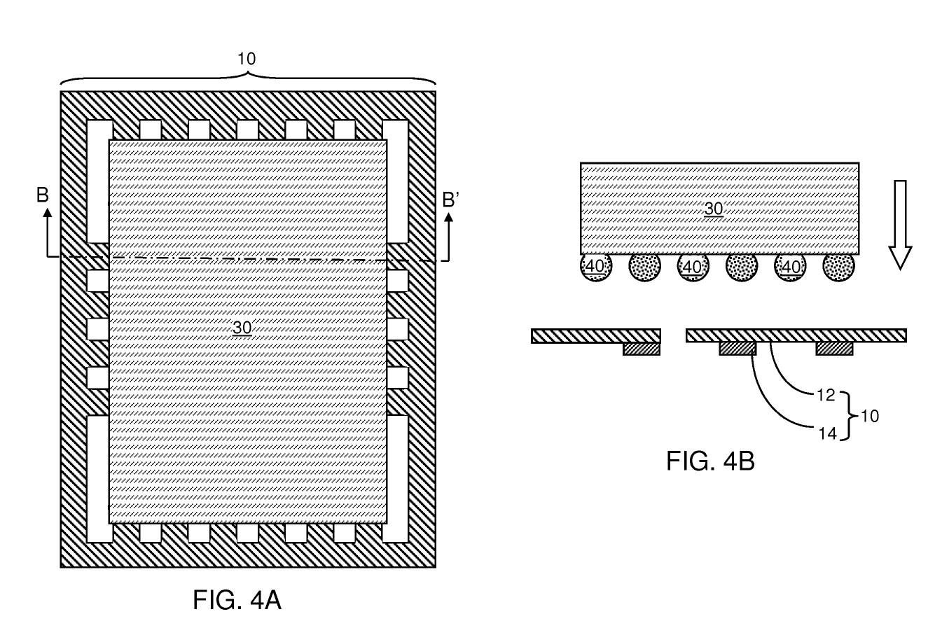

Referring to FIGS. 4A and 4B, solder balls 40 are bonded to a semiconductor chip 30 of the predetermined type, i.e., the type for which the leadframe 10 is designed. The semiconductor chip 30 includes at least one semiconductor device therein. The solder balls 40 can be any type of ball that can be bonded to a semiconductor chip 30 including controlled collapse chip connection (C4) balls. Typically, the C4 balls have a diameter from 50 microns to 200 microns, and a pitch from 100 microns to 400 microns, although lesser and greater pitches can also be employed. The assembly of the semiconductor chip 30 and the solder balls 40 is brought into contact with the leadframe 10 such that the solder balls 40 contact the top surface of the planar patterned metal structure 12, i.e., the surface of the planar patterned metal structure 12 located on the opposite side of the metal pads 14.

Each planar metal wiring structures in the planar patterned metal structure 12 is bonded to at least one solder ball 40. Upon bonding of the solder balls 40 to the leadframe 10, therefore, each planar metal wiring structure in the planar patterned metal structure 12 is structurally secured to the semiconductor chip 30 through at least one solder ball 40.

The resulting structure is a bonded structure including the semiconductor chip 30, an array of solder balls 40, and the leadframe 10 that is bonded to the solder balls 40 and is mechanically secured to the semiconductor chip 30 through the array of solder balls 40. Within the bonded structure (30, 40, 10), top surfaces of the planar metal wiring structure are coplanar among one another.

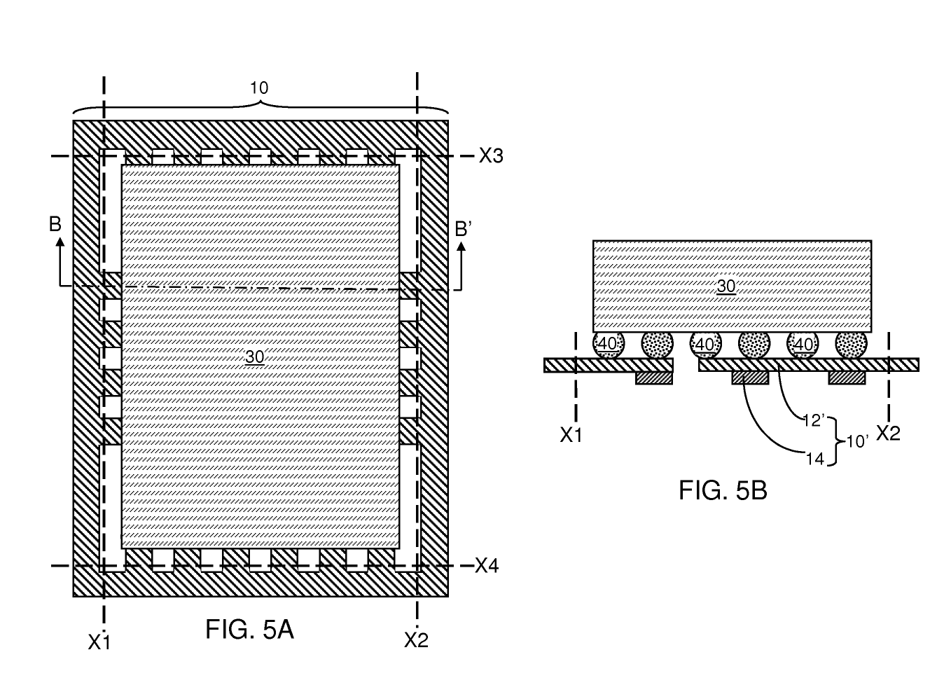

Referring to FIGS. 5A and 5B, the periphery of the leadframe 10 is truncated so that each planar metal wiring structure is electrically isolated from other planar metal wiring structures in the leadframe 10. For example, the leadframe 10 can be truncated along the direction parallel to the sidewalls of the semiconductor chip 30. For example, the illustrated leadframe 10 can be truncated along the planes X1, X2, X3, and X4. Any known means for truncating metal, including mechanical cutting and laser cutting, can be employed to truncate the leadframe 10. In other embodiments, the truncation of the leadframe 10 can occur at a different processing step such as immediately after application of dielectric molding compound, immediately after attaching the ball grid array (BGA) balls, or immediately after any other processing step that occurs after the application of the dielectric molding compound. In some embodiments, delaying the truncation of the leadframe 10 until a later processing step can provide some benefit in terms of process control.

The leadframe 10 becomes a collection of planar metal wiring structures having coplanar top surfaces that contact the solder balls, but not laterally contacting any other planar metal wiring structure. Because each planar metal wiring structure in the leadframe 10 is connected to at least one solder ball 40, each planar metal wiring structure in the leadframe 10 as truncated is structurally secured to the semiconductor chip 30 through the array of solder balls 40. Thus, peripheral portions of a patterned single metal sheet in the form of the leadframe 10 are truncated. The remaining portion of the leadframe 10 after truncation is referred to as a set of lead structures 10′. The resulting structure is a bonded structure including the semiconductor chip 30, an array of solder balls 40, and the set of lead structures 10′ that is bonded to the solder balls 40 and is mechanically secured to the semiconductor chip 30 through the array of solder balls 40.

The remaining portions of the planar patterned metal structure 12 include a plurality of planar metal wiring structures 12′. Each lead structure 10′ includes an integral construction of a planar metal wiring structure 12′ located on one side and at least one metal pad 14 protruding from a surface of the planar metal wiring structure 12′ on the other side.

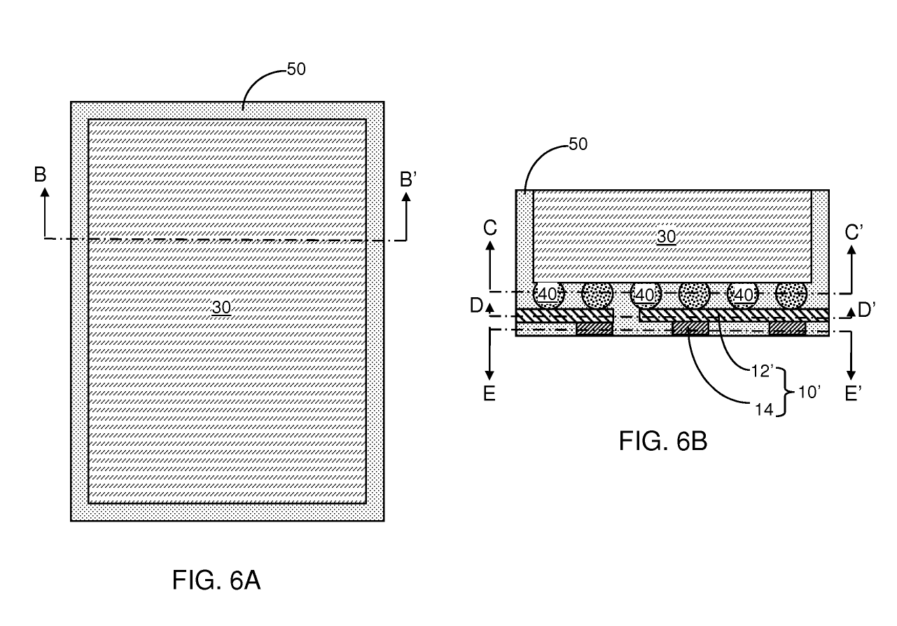

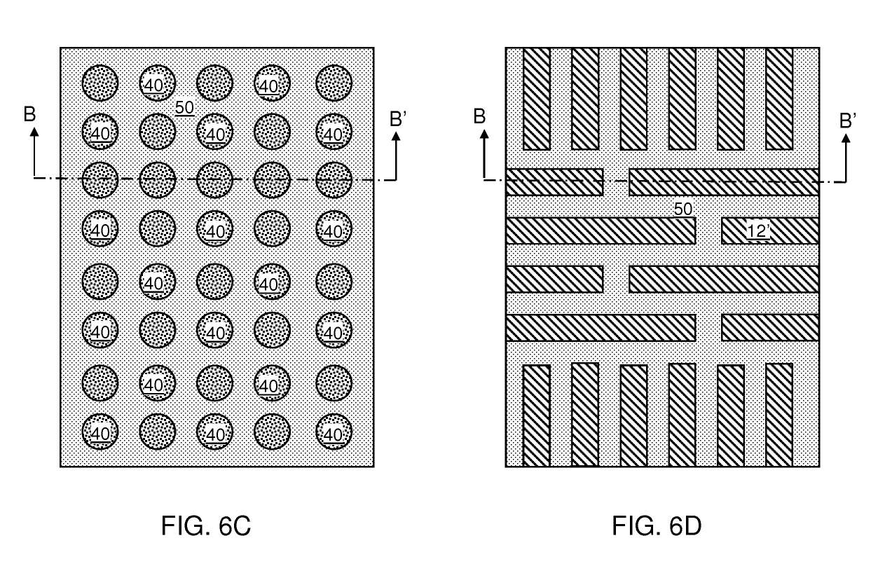

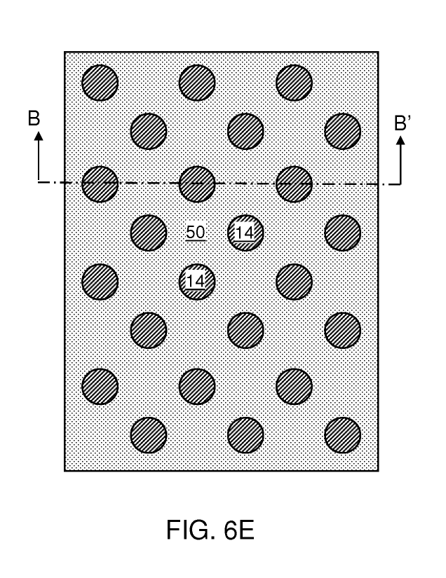

Referring to FIGS. 6A-6E, a dielectric molding compound is applied to the bonded structure (30, 40, 10′) to form a composite structure. The composite structure includes the bonded structure (30, 40 10′) and a dielectric molding compound structure 50 of integral construction, i.e., as a unitary structure. Within the bonded structure (30, 40. 10′), the set of lead structures 10′ is bonded to the solder balls 40. Each lead structure 10′ includes an integral construction of a planar metal wiring structure 12′ and at least one metal pad 14. The dielectric molding compound structure 50 can completely fill, and embed, all spaced between the semiconductor chip 30, the solder balls 40, and the set of lead structures 10′.

As a unitary structure, the dielectric molding compound structure 50 is contiguous throughout the entirety thereof. Thus, for any two arbitrarily chosen points within the dielectric molding compound structure 50, there exists at least one continuous path confined within the volume of the dielectric molding compound structure 50 that connects the two points. Thus, by embedding the bonded structure (30, 40, 10′), the dielectric molding compound structure 50 can provide structural support to the bonded structure (30, 40, 10′). The dielectric molding compound structure 50, the set of lead frames 10′, and the semiconductor chip 30 encapsulate the array of solder balls 40. Further, all horizontal surfaces of the planar metal wiring structure 12′ contact the dielectric molding compound structure 50. In addition, the entirety of the sidewall surfaces (i.e., vertical surfaces) of the metal pads 14 can contact the dielectric molding compound structure 50.

The dielectric molding compound structure 50 includes a dielectric molding compound material known as plastic molding compounds in the art. The molding compound material can be composite materials including epoxy resins, phenolic hardeners, silicas, catalysts, pigments, and mold release agents. Many types of molding compound materials can be employed. In general, molding compound materials having a low moisture absorption rate and/or a high flexural strength at board-mounting temperatures are preferred.

The dielectric molding compound material is molded so that all portions of the dielectric molding compound structure 50 are contiguously connected among one another, thereby forming a structure of unitary construction. The various surfaces of the bonded structure (30, 40, 10′) can be employed as a surface defining the outer extent of the dielectric molding compound structure 50. In one embodiment, the dielectric molding compound material can be molded to have a planar bottom surface that is coplanar with bottom surfaces of the metal pads 14. In this case, a planar bottom surface of the composite structure includes surfaces of metal pads 14 of the set of lead structures 10′ and a contiguous planar surface of the dielectric molding compound structure 50. The surfaces of metal pads 14 and the contiguous planar surface of the dielectric molding compound structure 50 complementarily fill a planar bottom surface of the composite structure. The exposed surfaces of the metal pads 14 are coplanar among one another and with the bottom surface of the dielectric molding compound structure 50.

Additionally or alternately, the dielectric molding compound material can be molded to have sidewalls that are coplanar with end surfaces of the planar metal wiring structures 12′, which are the sidewall surfaces formed at the time of truncation of the leadframe 10. In this case, the sidewall surfaces of the composite structure includes end surfaces of the planar metal wiring structures 12′ and sidewalls of the dielectric molding compound structure 50 that surround the end surfaces.

Additionally or alternately, the dielectric molding compound material can be molded to have a top surface that is coplanar with the top surface of the semiconductor chip 30. In this case, the top surface of the composite structure includes an exposed surface of the semiconductor chip 30 and a surface of the dielectric molding compound structure 50 surrounding a periphery of the exposed surface of the semiconductor chip 30.

Within the composite structure (30, 40, 10′, 50), each lead structure 10′ is laterally spaced from other lead structures 10′ by the dielectric molding compound structure 50. The top surfaces of the planar metal wiring structures 12′ are coplanar among one another. Each lead structure 10′ includes an integral construction of a planar metal wiring structure 12′ located on one side and at least one metal pad 14 protruding from a surface of the planar metal wiring structure 12′ on the other side. All planar metal wiring structures 12′ have a same thickness throughout areas that do not overlie the metal pads 14.

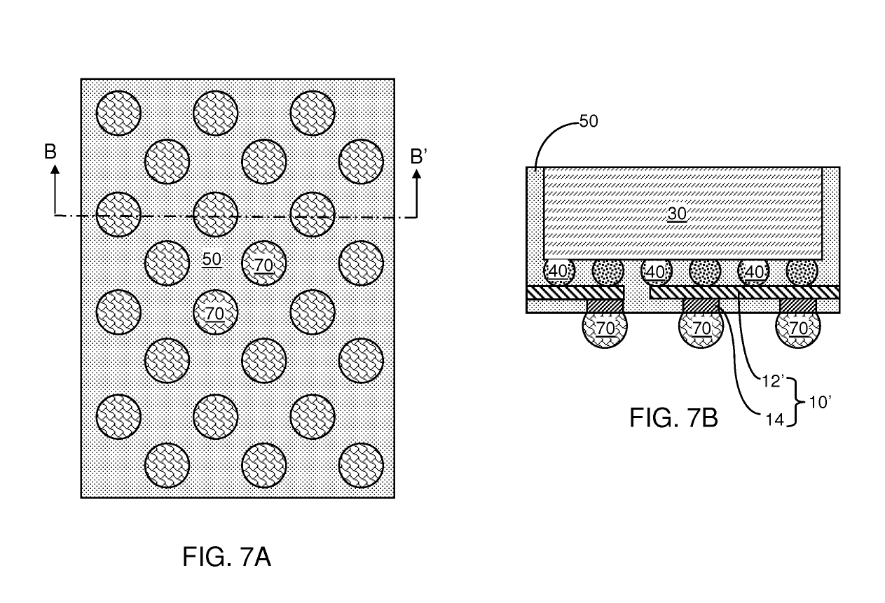

Referring to FIGS. 7A and 7B, ball grid array (BGA) balls 70 are attached to the composite structure (30, 40, 10′, 50). Specifically, the ball grid array (BGA) balls 70 are bonded to the exposed surfaces of the metal pads 14 of the lead structures 10′. The BGA balls 70 can have a diameter from 300 microns to 600 microns, and can have a pitch from 800 microns to 1,200 microns, although lesser and greater diameters and pitches can also be employed. The BGA balls 70 can be arranged in a pattern of an array.

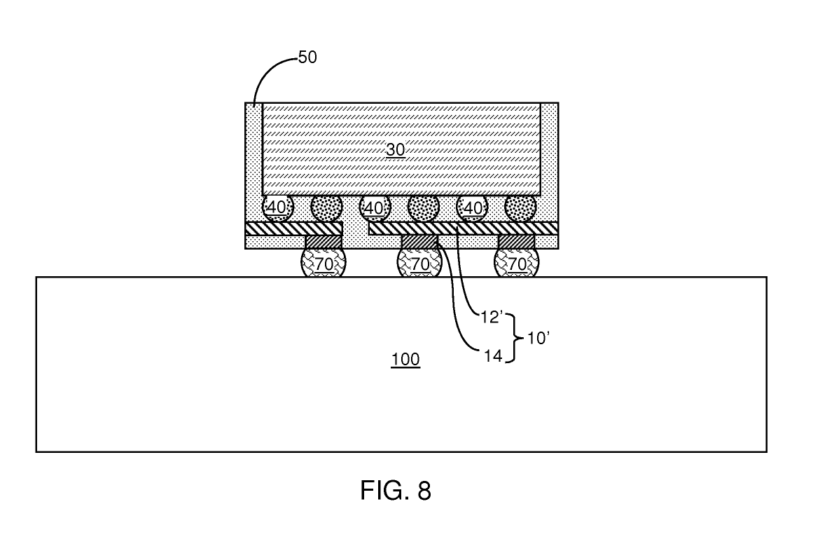

Referring to FIG. 8, the composite structure (30, 40, 10′, 50) is bonded to a substrate 100 through an array of the BGA balls 70. The array of the BGA balls 70 are bonded to bonding pads (not shown) provided on a surface of the substrate 100, which can be a printed circuit (PC) board. Because BGA balls 70 are employed to bond the composite structure (30, 40, 10′, 50) to the substrate 100, the standoff, i.e., spacing, between the bottom surface of the composite structure (30, 40, 10′, 50) and the substrate 100 is on the order of the diameter of the BGA balls 70, which can be from 300 microns to 600 microns. Thus, compared with prior art structures employing solder paste instead of BGA balls 70 and having a standoff less than 150 microns, the exemplary structure of FIG. 8 has a greater standoff and better protection against mechanical stress.

In addition, the dual layer structure of each lead structure 10′, which includes a vertical stack of a planar metal wiring structures 12′ and at least one metal pad 14 located thereupon, allows local wiring among the solder balls 40, so that current density through the BGA balls 70 can be optimized for maximizing total current carrying capacity and reliability.

While the disclosure has been described in terms of specific embodiments, it is evident in view of the foregoing description that numerous alternatives, modifications and variations will be apparent to those skilled in the art. Accordingly, the disclosure is intended to encompass all such alternatives, modifications and variations which fall within the scope and spirit of the disclosure and the following claims.

What is claimed is:

1. A packaging structure comprising a composite structure, said composite structure including:
a semiconductor chip including at least one semiconductor device therein;
solder balls bonded to said semiconductor chip;
a set of lead structures bonded to said solder balls, wherein each lead structure among said set of lead structures includes an integral construction of a planar metal wiring structure located on one side and at least one metal pad protruding from a surface of said planar metal wiring structure on the other side; and
a dielectric molding compound structure of integral construction, said dielectric molding compound structure embedding said semiconductor chip, said solder balls, and said set of lead structures.

2. The packaging structure of claim 1, wherein a planar bottom surface of said composite structure includes surfaces of metal pads of said set of lead structures and a contiguous planar surface of said dielectric molding compound structure complementarily filling said planar bottom surface with said surfaces of metal pads.

3. The packaging structure of claim 1, wherein top surface of said composite structure includes an exposed surface of said semiconductor chip and a surface of said dielectric molding compound structure surrounding a periphery of said exposed surface.

4. The packaging structure of claim 1, wherein sidewall surfaces of said composite structure includes end surfaces of said planar metal wiring structures and sidewalls of said dielectric molding compound structure that surround said end surfaces.

5. The packaging structure of claim 1, further comprising an array of ball grid array (BGA) balls that is bonded to surfaces of said metal pads.

6. The packaging structure of claim 5, further comprising a substrate bonded to said array of BGA balls.

7. The packaging structure of claim 6, wherein said substrate is a printed circuit board.

8. The packaging structure of claim 5, wherein top surfaces of said planar metal wiring structure are coplanar among one another, and said solder balls are bonded to top surfaces of said planar metal wiring structures.

9. The packaging structure of claim 1, wherein surfaces of said metal pads are coplanar among one another and with a bottom surface of said dielectric molding compound structure.

10. The packaging structure of claim 1, wherein each lead structure among said set of lead structures is laterally spaced from other lead structures by said dielectric molding compound structure.

11. The packaging structure of claim 1, wherein all planar metal wiring structures among said set of lead structures have a same thickness.

12. The packaging structure of claim 1, wherein said planar metal wiring structured and said metal pads have a same material composition.

13. A method of bonding a semiconductor chip to a substrate, said method comprising:
forming a composite structure including a semiconductor chip, solder balls bonded to said semiconductor chip, a set of lead structures bonded to said solder balls, and a dielectric molding compound structure of integral construction, said dielectric molding compound structure embedding said semiconductor chip, said solder balls, and said set of lead structures, wherein each lead structure among said set of lead structures includes an integral construction of a planar metal wiring structure located on one side and at least one metal pad protruding from a surface of said planar metal wiring structure on the other side;
bonding an array of ball grid array (BGA) balls to surfaces of said metal pads; and
bonding a substrate to said array of BGA balls.

14. The method of claim 13, wherein said composite structure is formed by:
bonding said solder balls to said semiconductor chip;
forming a bonded structure in which said set of lead structures is bonded to said solder balls; and
molding a dielectric molding compound material around said bonded structure to form said dielectric molding compound structure.

15. The method of claim 14, wherein said dielectric molding compound material is molded to have a planar bottom surface that is coplanar with bottom surfaces of said metal pads.

16. The method of claim 14, wherein said dielectric molding compound material is molded to have sidewalls that are coplanar with end surfaces of said planar metal wiring structures.

17. The method of claim 13, wherein said dielectric molding compound material is molded so that all portions of said dielectric molding compound structure are contiguously connected among one another.

18. The method of claim 13, wherein said planar metal wiring structures are formed to have a same thickness throughout areas that do not overlie said metal pads.

19. The method of claim 13, wherein said set of lead structures is formed by:
patterning a single metal sheet; and
truncating peripheral portions of said patterned single metal sheet, wherein remaining portions of said patterned single metal sheet are said set of lead structures.

20. The method of claim 19, wherein said single metal sheet is patterned by:
patterning a front surface of said metal sheet to include a pattern for said planar metal wiring structures; and
patterning a back surface of said metal sheet to include a pattern for said metal pads, wherein a center portion of each metal pad overlaps with one of said planar metal wiring structures.
